(19) United States
(12) Patent Application Publication
(10) Pub. No.: US 2024/0038621 A1
(43) Pub. Date: Feb. 1, 2024

(54) Device Comprising a Component and a Coupled Cooling Body

(71) Applicant: Siemens Aktiengesellschaft, München (DE)

(72) Inventors: Jörg Strogies, Berlin (DE); Matthias Heimann, Potsdam (DE); Bernd Müller, Falkenberg (DE); Klaus Wilke, Berlin (DE); Markus Pfeifer, Nürnberg (DE)

(73) Assignee: Siemens Aktiengesellschaft, München (DE)

(21) Appl. No.: 18/256,998

(22) PCT Filed: Oct. 29, 2021
(86) PCT No.: PCT/EP2021/080154

§ 371 Date: Jun. 12, 2023

(30) Foreign Application Priority Data
Dec. 15, 2020 (EP) 20214055.4

(51) Int. Cl. H01L 23/373; H01L 23/473

(52) U.S. Cl. CPC H01L 23/3733; H01L 23/473

(57) ABSTRACT

Various embodiments of the teachings herein include an apparatus comprising: a component; a cooling element; and a connecting element arranged between the component and the cooling element to thermally couple the cooling element to the component. The connecting element comprises a porous connecting body including a metal material. Pores of the connecting body are at least in part filled with a filling material including a low-melting alloy or a fluorinated organic liquid.

### CROSS-REFERENCE TO RELATED APPLICATIONS

This application is a U.S. National Stage Application of International Application No. PCT/EP2021/080154 filed Oct. 29, 2021, which designates the United States of America, and claims priority to EP Application No. 20214055.4 filed Dec. 15, 2020, the contents of which are hereby incorporated by reference in their entirety.

### TECHNICAL FIELD

The present disclosure relates to thermal management. Various embodiments of the teachings herein include systems and/or methods having a component, a cooling element, and a connecting element by which the component is thermally coupled to the cooling element.

### BACKGROUND

Typically, especially power electronics modules are particularly frequently connected to cooling elements in order to ensure the required dissipation of heat at ever increasing power dissipation densities and to reliably avoid overheating of the modules. In order to achieve this, the corresponding cooling elements are usually arranged particularly close to the power modules and an attempt is made to achieve the lowest possible thermal resistance when the cooling element is coupled to the module. In addition to this good thermal coupling, further requirements are frequently to be met in the region of the connection site. This includes for example a high durability of the mechanical and thermal properties of the connection under the operating conditions, including the temperature changes that occur during operation. Furthermore, it is often necessary for the entire apparatus to adhere to tight geometric tolerances and the production is to be possible altogether as cost-effectively as possible.

In order to solve this problem, in the prior art two different approaches prevail: In the case of the first customary solution approach, a soldered connection is produced between the cooling element and the component that is to be cooled. In this case, this is in other words a permanent connection with the disadvantage that it does not so easily allow for the exchange of one of the elements. Furthermore, it can be difficult in this case to adhere to the higher-level geometric tolerances since the deviations in the dimensions of the cooling element and power module, which are caused during production, can only be compensated with particular difficulty by controlled adaptations in the geometry of the solder layer. Finally, such a solder connection after its production is rigid with the result that during operation of the apparatus it is no longer possible to perform any retrospective compensation of geometric deviations from a desired measurement, which are possibly present.

In the case of the second customary solution approach, the cooling element is coupled by means of a heat conducting paste to the component that is to be cooled. Here in other words a detachable connection is provided and the connection is consequently maintained by virtue of the fact that the cooling element and component are pressed against one another both during assembly as well as during operation. Such a pressing can be realized by a hold down system that is known in principle in the prior art in which for example a contact pressure is generated via a spring or a clamping. One disadvantage of this type of coupling is that the thermal resistance is usually higher in comparison to the solder connection. A further disadvantage lies in the fact that the durability of the connection is frequently not particularly high in the event of high temperatures and in particular the possible intense temperature fluctuations that occur during operation. During longer periods of operation, it is thus possible for both the thermal resistance as well as the mechanical durability of such a connection to suffer. Furthermore, it is also difficult using a heat conducting paste to compensate in a defined manner for production tolerances that are present in the parts that are to be connected. Although the heat conducting paste renders possible a specific flexibility in the coupling, the precise setting of a target layer thickness in practice is nevertheless limited on account of the high deformability of the coupling medium.

### SUMMARY

The teachings of the present disclosure include systems having a component and a cooling element that is coupled thereto, which addresses the mentioned disadvantages. In some embodiments, an apparatus is to be provided that has a comparatively low thermal resistance for the coupling and simultaneously renders possible a flexible compensation of production tolerances due to a geometric adaptation of the connecting layer. Furthermore, the coupling is nevertheless to be realized in a relatively simple and cost-effective manner and is to be as durable as possible during operation.

As an example, some embodiments include an apparatus (1) having a component (100), a cooling element (200) and a connecting element (300) that is arranged between the component (100) and the cooling element (200) and that thermally couples the cooling element (200) to the component (100), wherein the connecting element (300) comprises a porous connecting body (310) that is made from a metal material, wherein the pores (311) of the connecting body (310) are at least in part filled with a filling material (320), wherein the filling material (320) has a low-melting alloy or a fluorinated organic liquid.

In some embodiments, the component (100) is a power electronics module or a power electronics component (130).

In some embodiments, the cooling body (200) has a surface enlarging structuring (210) and is formed in particular essentially from a metal material.

In some embodiments, the porous connecting body (310) is essentially open-pored.

In some embodiments, the volume fill factor of the porous connecting body (310) is in a range between 15% and 70%.

In some embodiments, the degree of filling of the filling material (320) in the pores of the porous connecting body (310) is between 25% and 80%.

In some embodiments, the filling material (320) is a liquid metal.

In some embodiments, the filling material (320) has a thermal conductivity of at least 10 W/m·K.

In some embodiments, the filling material (320) has a melting point between 200° C. and 300° C.

In some embodiments, the filling material (320) has a melting point between 100° C. and 200° C.

In some embodiments, the filling material (320) has a melting point below 100° C.

In some embodiments, the apparatus includes a compensating facility with which it is possible to compensate a change in volume of a filling material (320) that is contained in the connecting body (310) and that is liquid during operation of the apparatus.

As another example, some embodiments include a method for producing an apparatus (1) as described herein, the method comprising: a) coupling the porous connecting body (310) to the component (100), b) filling the porous connecting body (310) with the filling material (320), c) coupling the cooling element (200) to the connecting body (310).

In some embodiments, in step a) the connecting body (310) is applied to the component (100) by additive manufacturing.

In some embodiments, a gradient is produced in a geometric property of the connecting body.

### BRIEF DESCRIPTION OF THE DRAWINGS

The teachings of the present disclosure are further described below with the aid of some exemplary embodiments with reference to the attached drawings, in which:

FIG. 1 shows a schematic cross section of an apparatus incorporating teachings of the present disclosure; and

FIGS. 2 to 4 show various stages of the production of an exemplary apparatus incorporating teachings of the present disclosure.

In the figures, identical or functionally identical elements are provided with the same reference numerals.

### DETAILED DESCRIPTION

The teachings of the present disclosure include an apparatus comprising a component, a cooling element and a connecting element that is arranged between the component and the cooling element and that thermally couples the cooling element to the component. The connecting element comprises a porous connecting body that is made from a metal material, wherein the pores of the connecting body are at least in part filled with a filling material, wherein the filling material has a low-melting alloy or a fluorinated organic liquid.

The fundamental function of the connecting element is thus the thermal coupling of the cooling element to the component in order to ensure an effective dissipation of heat of the heat loss that is released in the component during operation of the apparatus. The connecting element is used so as to provide as low as possible a thermal resistance between the component and cooling element so that overall, a more effective transfer of heat is ensured from the component as a location of the dissipation to the cooling element than an actual heat sink of the apparatus. The thermal energy is dissipated to the environment of the apparatus by the cooling element, namely either to ambient air or also to another surrounding medium such as cooling water or cooling oil or another liquid or gaseous medium. In some embodiments, the connecting element in this case is the significant heat path between the component and the cooling element. Thus, in the event of multiple parallel heat paths being present between these two elements, then the heat path having the lowest thermal resistance is to be formed via the connecting element.

In some embodiments, a fixed element is provided in this thermal connection due to the porous connecting body and defined geometric properties and in particular a predefined spacing can be set due to this fixed element. In contrast to the connection using heat pastes or at least in the assembly state liquid solder, in other words in this case a fixed framework is present within the connection. Depending on the precise dimensions of this framework, fluctuations in the exact size and installation position of the elements that are to be connected can thus also be compensated. In this manner, the connecting body can contribute to adhering to the required geometric overall tolerances of the apparatus. Due to the porous nature of this solid connecting body, in this case simultaneously a specific mechanical flexibility is achieved with the result that even in the case of a provided original shape and original size of this connecting body, it is possible to further finely adjust the actual dimensions that are present in the installation situation.

In particular, it is possible due to the effect of a pressing force on the connecting body to cause a compression of the porous structure with the result that in dependence upon the selected force it is rendered possible to achieve a predefined target thickness. In dependence upon the fluctuations in the sizes and installation positions of the other components, this target thickness can be easily selected as different for each individual apparatus in a series of apparatuses that are to be produced, in order to provide a compensation of these fluctuations. In other words, a geometrically variable framework is provided in the connecting region.

The mechanical and geometric advantages of the porous connecting body that are described however are accompanied by a serious disadvantage, in the event of no further measures being taken: due to the presence of pores in this body, the thermal coupling between the component and the cooling element is weakened. This applies at least then if the interior space of the pores remain open and in this manner contribute little to the thermal path (or more precisely: if the pores are filled with air and due to the low thermal conductivity of the air provide a particularly small contribution to the coupling).

In some embodiments, the pores are at least in part filled with a filling material. This filling material is to be in particular a solid or liquid filling material or also a material that can change between a liquid and a solid state during operation of the apparatus. The filling material is thus in any case not gaseous. Due to this filling, it is achieved that the air proportion in the pores is displaced and the effective thermal conductivity of the connecting element is significantly improved in comparison to the unfilled connecting body. The extent of this improvement is dependent upon the degree of filling of the filling material and can be set in dependence upon the required thermal properties. In this manner, a particularly flexible “tuning” is possible between the desired geometric mechanic and the desired thermal properties of the connecting element.

In some embodiments, the method comprises:
a) coupling the porous connecting body to the component,
b) filling the porous connecting body with the filling material, and
c) coupling the cooling element to the connecting body.

A comparatively simple and cost-effective possibility is provided for producing an apparatus. The sequence of the steps is not to be limited to the disclosed sequence. On the contrary, there is a range of variation here for the selection of the sequence, within which it is possible to select the simplest production method for the specific boundary conditions. It is only essential that overall, a filled connecting body is thus provided that is coupled thermally to the two elements that are to be coupled, in order to thus achieve the advantages described herein.

In some embodiments, the component can thus be in particular a power electronics module or a power electronics component. Power dissipation densities in the region of the power electronics in general are particularly high and increase more and more with increasing power with the result that here the design of a heat path that is as efficient as possible is particularly important. In some embodiments, a power electronics component can comprise for example a power transistor, in particular an IGBT.

In general and independent of the type and power class of the component, this can represent either an individual component or a module. In this case, a module is to be understood to mean in particular a compact circuit unit of multiple individual components. Such a module often also includes a wiring carrier (in particular a board), via which it is possible to realize the coupling to the cooling element. The thermal coupling can however in principle also be provided directly to the component in a module. The fundamental objective in the case of the thermal coupling to a cooling element is in any case independent of whether the component is a module or an individual component.

In some embodiments, the cooling element can have a surface enlarging structuring, for example in the form of ribs, lamellae or also in the form of a star-shaped heat dissipator or more ramified cooling structures. In this manner, the cooling element can cause the dissipation of heat to the surrounding medium in a particularly effective manner. Such a cooling element can be formed in particular essentially from a metal material or can comprise such a material at least as a main component. In this context, aluminum, copper or an alloy that is based on at least one of these metals may provide good thermal energy transfer qualities. In some embodiments, it is however also possible here to use other materials having a high degree of thermal conductivity, for example ceramics such as aluminum oxide or aluminum nitride or composite materials that can have in part in turn a metal material as a component. In some embodiments, the cooling element can also be coated with a functional coating. It is thus possible for an aluminum-based cooling element to be coated with a nickel coating in order to achieve an inertization, in particular even with respect to reactive materials that can be used as filling material of the connecting body.

In some embodiments, the porous connecting body is formed from a metal material. Due to the high degree of thermal conductivity of metals, an effective transport of heat can already take place via the pore framework. Metal pore frameworks can be deformed relatively effectively without being destroyed since they are not particularly brittle. In this manner, it is possible using such a flexible framework material to realize the geometric adaptation possibility that is mentioned above. Copper or a copper-based alloy is in turn particularly suitable for this purpose. Similar to in the case of the cooling element, a functional coating, in particular having a comparatively inert material, which prevents a reaction of the connecting body with the filling material that is filled therein, can also be expedient in the case of the framework material of the connecting body. This can also be for example a nickel-based coating here.

In some embodiments, the connecting body is designed so that it can deform without being destroyed. A change in thickness of the connecting element and thus a change in the spacing between the component and the cooling element can thus be caused independent of the effect of a pressure force. In principle, it is possible in this case either for it to be more of an ability to deform in an elastic manner or also more of an ability to deform in a plastic manner. In the case of the plastic deformation, it is possible by means of a pressure force to cause a permanent geometric change. In the case of the elastic deformation, conversely a restoring force results, which counteracts the pressing force and in this manner renders possible a variable, force-dependent geometric adaptation. In order to achieve an optimal geometric adaptation, an interaction between plastic and elastic deformation can also be desirable.

In some embodiments, the porous connecting body can be essentially open-pored. In the case of such an open-pored body, the hollow spaces of the individual pores are connected via passages both to one another as well as to the exterior environment with the result that a network of hollow spaces and thus a higher-level porosity results. This has the effect that the porous connecting body can be retrospectively (in other words after the production process of the porous structure) filled with a filling material. The design of the framework and the filling with the filling material can thus be provided in two separate steps, which overall simplifies the production. In some embodiments, the filling with the filling material is already provided during the formation of the porous structure. In the case of this variant, a closed-pored connecting body can then also be used. Mixed forms are also conceivable in which the hollow spaces are in part closed and in part are connected to one another.

In some embodiments, the volume fill factor of the porous connecting body is in a range between 15% and 70%. This volume fill factor is to be understood to mean the volume proportion of the connecting element that is provided by the framework material and not by the hollow spaces of the pores. If this volume fill factor is particularly low, the mechanical stability of the framework structure is at risk. Conversely, if this volume fill factor is particularly high, then the ability to deform is weak.

In the mentioned range, it is possible using the connecting body to achieve both a fundamental mechanical stability as well as a sufficient ability to deform.

The filling material of the porous connecting body can have a metal material. This can be in particular a low-melting alloy such as for example a solder material or a liquid metal. In some embodiments, the filling material can however also comprise a fluorinated organic liquid. This can be for example a perfluorotributylamine. Such liquids are distributed by the company 3M under the trade name “Fluorinert”. One example is “Fluorinert FC-43” that is used in particular in the prior art as a coolant.

In some embodiments, the filling material is at least liquid during the assembly of the apparatus with the result that a geometric adaptation is possible via a deformation of the connecting body that is to be filled or is currently being filled. During the operation of the apparatus, the filling material can then either be solid or liquid or also can pass through an occasional phase change between these two aggregate states depending on the operating temperature and melting range.

In general and independent of the precise selection of material and melting range, in some embodiments the filling material has a thermal conductivity of at least 10 W/m·K. It is possible with such a thermally well-conductive filling material altogether to achieve an effective thermal coupling via the connecting element due to the displacement of the air from the pores. Even if the material of the pore framework is not particularly thermally conductive, it is thus possible in dependence upon the degree of filling to nevertheless altogether still achieve a moderate to highly effective overall thermal conductivity.

Altogether, a type of parallel circuit results between the heat path of the framework and the heat path of the filling material. It is possible due to the precise selection of the materials and the degree of filling to set the effective overall conductivity in a particularly targeted manner, wherein simultaneously the other, in particular mechanical geometric requirements are likewise taken into account. In some embodiments, for example to achieve an effective overall thermal conductivity of the connecting element of 10 W/m·K or more.

In some embodiments, the degree of filling (in other words the proportion to which the pore volume is filled with the filling material) is between 25% and 80%. In principle, the degree of filling can also be even lower and even amount to only a few percent, however the contribution of the filling material to the thermal conductivity is then relatively low. On the other hand, the degree of filling can also be up to 90% or up to 95% or even higher, which accordingly further increases the contribution to the thermal conductivity. However, a complete filling of the pore framework in practice is often difficult since firstly not all the pores are open to the exterior and secondly the wetting of the filling material will not always be optimal for the material of the connecting body.

As mentioned above, multiple possibilities result for the aggregate state of the filling material. In some embodiments, the filling material during assembly (in particular during the filling of the connecting body) can be liquid, however during the operation of the apparatus can be solid. The melting point of the filling material is then selected so that the melting point is above the maximum operating temperature that occurs.

It is thus possible in the case of this variant for the melting point or the melting range of the filling material in general to be above 200° C. and in particular between 200° C. and 300° C. The filling material can be in other words in particular a corresponding soldering alloy. Typical assembly temperatures at which such a solder can be filled as a filling material into the connecting body are for example in the range between approximately 230° C. and 260° C. The predetermined temperature range for the operation of the apparatus can be selected so that the maximum operating temperature does not exceed a value of 200° C. In the case of typical power modules, the maximum operating temperatures can lie for example in a range between approximately 150° C. and approximately 200° C.

Suitable solder alloys here can be for example tin-based solders, in particular tin-silver-copper solders (abbreviated SAC, having for example approximately 3% silver proportion and approximately copper proportion and a melting range between 217° C. and 219° C.) or tin-antimony solder (having for example approximately 95% tin and approximately 5% antimony and a melting range between 232° C. and 240° C.)

A significant advantage of this variant is that due to the permanently solid filling material, even during operation of the apparatus a high degree of stability is provided. During operation there are also thus no problems with possible changes in the degree of filling or the encapsulation of the connecting element. However, the connecting element during operation is also less easily deformable than in the case of liquid filling materials. A geometric adaptation is therefore primarily limited to the assembly step. This can however suffice throughout in order to be able to compensate fluctuations in size and installation position of the elements that are to be connected. In some embodiments, the filling material reacts with the material of the connecting body in the contact region and forms a diffusion joint connection there. In this manner, it is possible to form a higher-level solid body having comparatively homogenous properties from the two materials. In the case of the other two variants having (at least in part) liquid filling material, such a reaction is conversely rather disadvantageous and should be avoided as far as possible by a corresponding material selection or an inertization of the surface of the connecting body.

In some embodiments, the filling material can be liquid during the assembly, and during the operation of the apparatus can change between a liquid and a solid state. The melting point of the filling material is then selected in such a manner that it is below the maximum operating temperature that occurs but is above the minimum operating temperature that occurs. In the case of this variant, it is thus possible for the melting point or the melting range of the filling material in general to be between 100° C. and 200° C. The filling material can be in other words in particular a corresponding low temperature solder alloy.

Suitable solder alloys here can be for example tin bismuth based solder (for example Sn43Bi58 having a melting point of 138° C.) or indium tin based solder (for example having melting ranges between approximately 118° C. and 131° C.) or tin antimony based solder (for example having a melting point of approximately 139° C.). In the case of this second embodiment variant, it is thus likewise still possible to use comparatively common solder materials. Owing to the occasional transition into the liquid aggregate state during operation, it is also possible for a geometric adaptation of the connecting element to be performed in the operating state.

In some embodiments, the filling material can be liquid during assembly and also can be liquid during the operation of the apparatus (at least typically). The melting point of the filling material is then selected so that it is below the (typical) minimum operating temperature. In the case of this variant, the melting point or the melting range of the filling material in general can be below 100° C. The filling material can thus be in particular a liquid metal or another type of coolant, for example a fluorinated organic liquid and in particular a Fluorinert.

In some embodiments, a liquid metal can comprise gallium, indium, tin and/or quicksilver. Metals of this type may achieve a low melting point in a metal alloy. In some embodiments, the liquid metal has both gallium as well as indium and tin. In some embodiments, the liquid metal is even exclusively made from the three mentioned metals. For example, the liquid can be an alloy that is known to experts under the name Galinstan. Galinstan is a eutectic alloy that has approximately 68.5 weight percent gallium and also approximately 21.5 weight percent indium and approximately 10 weight percent tin. Such an alloy has a particularly low melting point of approximately −19° C. Other suitable low-melting alloys are available for example under the names Indalloy 51 and Indalloy 60 from the US company Indium corporation in Utica NY. Further suitable gallium based alloys are for example the alloys that are described in the patent documents U.S. Pat. No. 5,800,060B1 and U.S. Pat. No. 7,726,972B1. In addition to the three mentioned metals, they can also comprise additives of other metals such as for example zinc (in particular between approximately 2 and 10 weight percent).

The alloys that are described, which are based on gallium, indium and/or tin, have a low toxicity and consequently are relatively harmless in relation to damage to health and the environment. Quicksilver is likewise a suitable liquid metal or a suitable alloy component for low-melting alloys, however has the fundamental disadvantage that it is highly toxic.

In general, and independent of its precise composition, the metal liquid can be a eutectic alloy. Such an alloy may achieve a significantly lower melting point than using the individual metal components of the alloy.

Liquid metals with the solder alloys that are described further above together are comparatively highly thermally conductive. In contrast thereto, non-metal liquids are typically significantly less thermally conductive. However, in such non-metal liquids the contribution of the convection to the overall transport of heat can be clearly higher with the result that such materials—and in particular the mentioned Fluorinerts—can nevertheless be fundamentally questioned as filling materials.

A fundamental difficulty in the case of the second and third variants is that due to the (at least in part) liquid filling material a reliable encapsulation of the porous connecting body with respect to outside is required. Expediently, the connecting body is therefore surrounded (either prior to or after the filling procedure) by a suitable encapsulation or cladding. Furthermore, in particular in the case of the second and third variants, a compensating facility can be provided with which it is possible to compensate a change in volume of a filling material that is contained in the connecting body and that is liquid during operation of the apparatus. For example, a compensating reservoir can thus be provided that is fluidically connected to the filling material within the connecting body.

According to the principle of communicating tubes, changes in the quantity of liquid filling material that is received in the connecting body can thus be compensated. It is also possible to provide a variable adaptation of the thickness of the connecting element (and consequently the spacing between cooling element and component) in order for example to counteract changes in the ability to receive the connecting body, which are caused on account of temperature. Such a level adaptation can for example be force-controlled, wherein in particular a pressing force that is acting upon the cooling element can be varied.

The case is however also conceivable that in the case of the second and third variant an external compensating facility for the filling material can also be omitted. This is in particular then the case if the pores in the starting state are not entirely filled with the result that in the case of a compression of the pore framework, the degree of filling is automatically increased. In other words, a compensating mechanism for the filling volume is already integrated here into the pore framework that is not entirely filled. In the case of this variant, an entirely liquid-tight encapsulation of the connecting element with respect to the external environment is therefore also possible.

As is already mentioned further above, the sequence of the method steps a), b) and c) that are described is fundamentally arbitrary with the result that multiple possible variants are possible here for the process sequence. In some embodiments, it is thus possible to perform step b), in other words the filling of the porous connecting body with the filling material, separately and in particular prior to the other steps with the result that a pre-assembled filled component is formed. As a consequence, the coupling of the part elements in the steps a) and c) are handled in a similar manner to in the prior art, which clearly simplifies the production. In some embodiments, the filling step b) can however also be performed “in situ” in other words thus closely linked to the formation of the coupling. For example, the filling step can be performed after step a) but prior to step c). In other words, the filling is then performed after the connecting body has already been coupled to the component but before the cooling element is mounted. In some embodiments, it is however also possible that steps a) and c) are performed beforehand, in other words the connection of the component and the cooling element is already provided via the connecting element and the filling is performed in accordance with step b) only at the very end, for example due to infiltration of the connecting body from the side.

In some embodiments, both the coupling of the connecting body to the component in accordance with step a) as well as the coupling of the cooling element to the connecting body in accordance with step c) can be performed in a reversible manner. In other words, a permanent (in particular not integrally bonded) connection is not provided but rather it suffices if the individual elements are connected to one another by a pressing force. In the case of this variant, the connecting element is a so-called “insert” in other words a loose inserted intermediate layer that advantageously can be dismantled in a non-destructive manner in order to make changes to the apparatus. In general, and independent of whether a firm bond is provided between the individual elements or not, the connecting element can be advantageously designed as flat and mat-like and in this case in particular can have a uniform thickness.

In an alternative to the loose stack one above the other that is described above, in some embodiments, in step a) and/or in step c) a firm, integrally bonded bond is provided. This can then be the case in particular if in step a) the connecting body is applied to the component by additive manufacturing. This embodiment can be used to produce a porous body having a fixedly defined and in certain circumstances also geometrically complex pore properties. In an alternative to this application “in situ” by additive manufacturing, the porous connecting body can also be produced beforehand in an additive manner for example as a pre-assembled component. In general, the additive manufacturing of the connecting body opens up possibilities for shaping that in the case of classic production are not achieved at all or are achieved in a less precise manner or are achieved in at least a less simple manner.

In some embodiments, it is possible due to additive manufacturing of the connecting body to produce a gradient in one of its geometric properties. This can be in particular a gradient above a coating thickness (in other words in the direction of the spacing between the component and cooling element). For example, it is possible due to the focused variation of the additive manufacturing parameters to provide a gradient in the case of the pore proportion (in other words in the case of the opened volume) in the case of the pore size and/or in the case of the extent of cross linking of the pores.

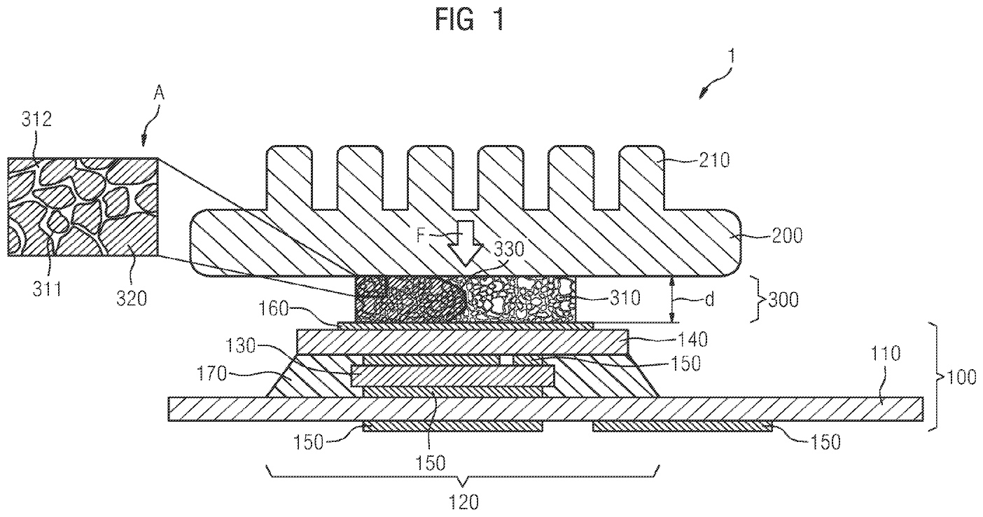

FIG. 1 illustrates a schematic cross section of an apparatus 1 incorporating teachings of the present disclosure. This apparatus 1 includes a component 100 that is coupled via a connecting element 300 thermally to a cooling element 200. A dissipation of the heat loss that is released during the operation of the component 100 is caused via this thermal path. The component in this example is a module that includes a power electronics component 130.

The majority of the heat loss of the module is released in this power electronics component 130, which is why the thermal coupling to the cooling element 200 is also realized in the vicinity of the component 130. The module however comprises further elements, inter alia a main wiring carrier 110 that can optionally also carry yet further electronic components that are not illustrated here. A further wiring carrier 140 is arranged on the side of the power electronics component 130 that is remote from the main wiring carrier and the further wiring carrier is allocated to the individual component 130. The two wiring carriers 110 and 140 are electrically connected to the component 130 and also to further elements that are not explicitly illustrated here via metallization layers 150. The main wiring carrier 110 can be connected to an external current circuit or to further electrical or electronic apparatuses via further underlying metallizations 150. The region of the power electronics functional unit 120 is cast using a casting resin 170 so as to encapsulate with respect to the external environment.

The thermal coupling of the power electronic functional unit 120 to the cooling element 200 is realized due to a flat mat-like connecting element 300. This is thermally coupled to the wiring carrier 140 via a metallization layer 160. This arrangement is however only to be understood as exemplary and the coupling could in principle also be performed in other regions of the module. In particular, an individual (power) electronics component 130 could be directly coupled to the connecting element 300, in other words without an intermediate-connected wiring carrier 140. The connecting element 300 can be inserted loose or also can be permanently connected to the component 100 or the cooling element 200.

The connecting element 300 has a connecting body 310 that is designed as a pore framework as is apparent in the enlarged section A. The material of this pore framework 312 can be for example a metal material. In the enlarged section, only as an example an embodiment having a comparatively small volume fill factor of the framework material and an accordingly high volume proportion of the pores 311 is illustrated. This is however only to be understood as exemplary and the volume fill factor of the framework can in practice vary over a broad value range in dependence upon the thermal and mechanical geometric requirements. In the illustrated example, the porous connecting body 310 is open pored, in other words the individual pores 311 are at least for the most part connected to one another via passages to a higher-level network.

FIG. 1 illustrates a state in which the pores 311 of the connecting body 310 are only filled in the left-hand side part of the drawing with a filling material 320. In the region of the enlarged section A a significant part of the open pore 311 is thus filled by the filling material 320. In the right-hand side part of the figure, the connecting body 310 however is not yet infiltrated with the filling material 320. There can be for example a process stage here in which the connecting body 310 is infiltrated with the liquid filling material 320 with the result that in the central region a liquid front 330 results. At least in the case of this process step, during the infiltration of the porous body, the filling material 320 is a liquid material. Later, during the operation of the apparatus, the filling material 320 can be liquid or solid or can switch between these two aggregate states. Merely in an exemplary manner, a state is illustrated in section A in which the pores 311 are essentially entirely filled. In practice, it is also possible to only reach a significantly lower degree of filling, in particular if a part of the pores is particularly small and the wetting properties are not sufficient for a complete filling.

In any case, due to the at least proportionate filling of the pores 311 with the filling material 320 it is achieved that air from the pores 311 is displaced and is replaced by a material having an increased thermal conductivity (in comparison to air). The thermal conductivity of the connecting body 310 is consequently increased in comparison with the unfilled state. In this manner, the thermal coupling to the cooling element 200 is significantly improved. In the case of the example of FIG. 1, the cooling element 200 has a plurality of cooling ribs 210 in order to facilitate the dissipation of heat from the cooling element to the environment. In order to ensure the connection of the cooling element 200 to the connecting element 300, the cooling element 200 is pressed using a pressing force F onto the connecting element 310 and thus indirectly also the remaining parts of the power electronics functional unit 120. This pressing is achieved for example via a hold down system that is not further illustrated here. In dependence upon the selected pressing force F, it is possible for the connecting element 300 to be compressed to a varying extent.

In some embodiments, the porous embodiment of the connecting element leads to a mechanical ability to deform with the result that the thickness d of the connecting body can be varied in dependence upon the force F. In this manner, it is possible to set the thickness d in a targeted manner and it is possible to compensate fluctuations, which are caused by the production process, in the size and installation position of the elements 100 and 200 that are to be connected. This ability of the connecting body 310 to deform is also provided in the filled state at least as long as the filling material 320 is in a liquid aggregate state. At least during the assembly, a geometric adaptation is possible. If the filling material has such a low melting point that it is (in part) liquid during operation of the apparatus, then in this case a further geometric adaptation is also possible.

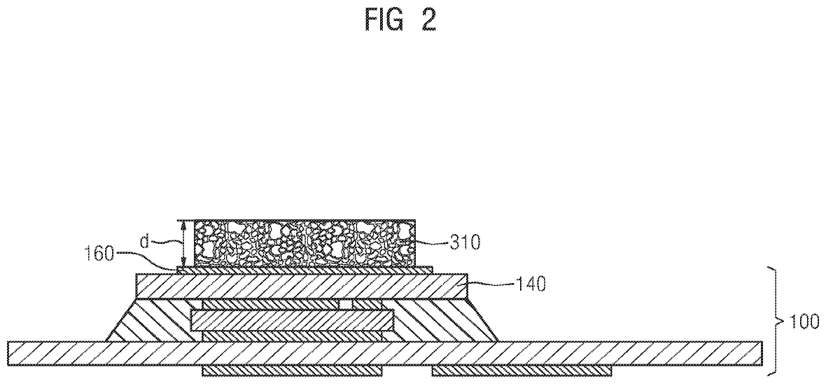

Different stages of the production of an apparatus 1 incorporating teachings of the present disclosure are illustrated in FIGS. 2 to 4. In this case, the finished apparatus is altogether designed in a particularly similar manner to the example of FIG. 1. FIG. 2 illustrates a process stage in which the connecting body 310 of the connecting element is already applied to the component 100 but is not yet filled with the filling material. The connecting body 310 can also be placed loose here according to a type of an insert. It is particularly preferred however if the connecting body is produced “in situ” on the component 100 by additive manufacturing. As a consequence, the connecting body 310 for example is permanently connected to the metallization layer 160 of the wiring carrier 140. This permanent connection can however also be provided at another position, in particular on the (power electronics) component 130 itself. Due to the additive manufacturing, it is possible for example to produce a gradient of specific properties of the pore framework in the direction of the thickness d. In some embodiments, it is however also possible to produce a gradient in another spatial direction or various gradients in relation to various properties can be superimposed. The varied property can be in particular a geometric property such as for example the pore size, the geometric fill factor of the pore framework and/or the degree of wetting of the pores. However, it can also be a gradient in the material composition of the pore framework.

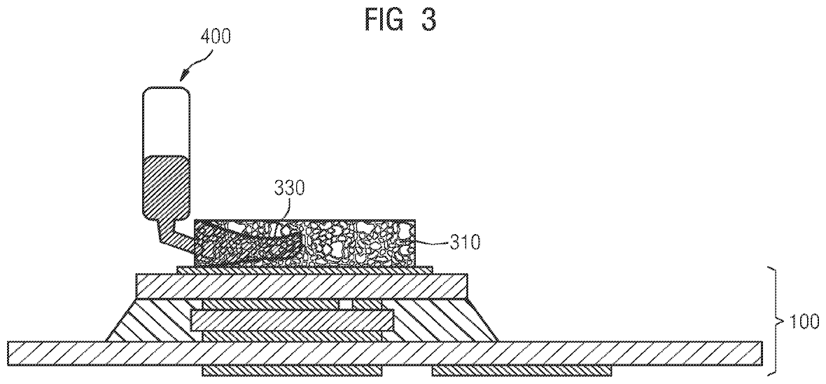

FIG. 3 illustrates a subsequent process stage in which the connecting body 310 that is manufactured is filled with the filling material “in situ”. For this purpose, a dosing facility 400, which is only illustrated schematically, is connected to the connecting body 310. This can, as is illustrated here, be provided on the side of the connecting body or also in principle from the upper side that is still open. A liquid front 330 is also apparent here since the connecting body 310 is only in part filled with the filling material. In contrast to the example of FIG. 1, in other words the filling here is performed prior to coupling the cooling element.

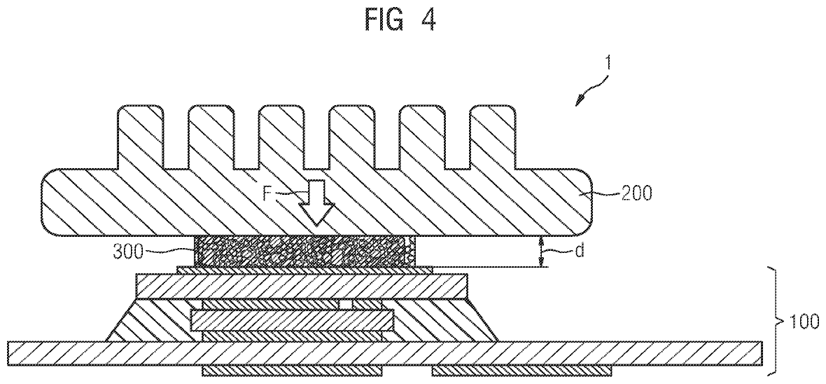

FIG. 4 illustrates a subsequent state of the apparatus 1 in which the cooling element 200 is coupled to the connecting element 300 that has meanwhile been completely filled. In a similar manner as in the example of FIG. 1, the cooling element is pressed using a pressing force F onto the connecting element 300. Due to the mechanical flexibility, the mat-like connecting element 300 is pressed together owing to the pressing force F with the result that the thickness d of the connecting element is reduced in comparison to FIGS. 2 and 3. In this manner, in dependence upon the force it is possible to set a desired thickness at least as long as the filling material is still liquid. This thickness difference is however illustrated in a greatly exaggerated manner. The pressing force can thus be designed in particular as relatively small, in particular if only small geometric adaptations are required. Since the wetting of the cooling element 200 by the liquid filling material can contribute to the coupling of the cooling element, this pressing force can advantageously be selected as smaller than in the case of the prior art.

In the event of the filling material during the operation of the apparatus also remaining (at least in part) in the liquid state, it can be advantageous to encapsulate the connecting element with respect to the external environment at least in the region of the circumferential side limiting surface. Such an encapsulation can also entirely clad the connecting element with the result that this connecting element in the manufactured state can no longer emit any liquid filling material to the environment. In an alternative to this entire encapsulation, it is however also possible to provide an external compensating facility that in particular in the case of an intense compression of the connecting element can receive the escaping filling material and in the case of a decompression can emit again. For this purpose, for example a compensating container can be provided that in a similar manner to the dosing facility in FIG. 3 (however in the final constructed state, in other words on the apparatus including the cooling element) in the side region of the connecting element is fluidically connected to the interior space of the pore framework.

### LIST OF REFERENCE CHARACTERS

1 Apparatus
100 Component
110 Main wiring carrier
120 Power electronics functional unit
130 Power electronics component
140 Wiring carrier of the power electronics unit
150 Metallization layers
160 Metallization layer
170 Casting resin
200 Cooling element
210 Cooling ribs
300 Connecting element
310 Connecting body
311 Pore
312 Pore framework
320 Filling material
330 Liquid front
400 Dosing facility
A Enlarged section
d Thickness of the connecting element
F Pressing force

What is claimed is:

1. An apparatus comprising:
a component;
a cooling element; and
a connecting element arranged between the component and the cooling element to thermally couple the cooling element to the component;
wherein the connecting element comprises a porous connecting body including a metal material; and
pores of the connecting body are at least in part filled with a filling material including a low-melting alloy or a fluorinated organic liquid.

2. The apparatus as claimed in claim 1, wherein the component comprises a power electronics module or a power electronics component.

3. The apparatus as claimed in claim 1, wherein the cooling body has a structure enlarging a surface area and essentially consists of a metal material.

4. The apparatus as claimed in claim 1, wherein the porous connecting body is open-pored.

5. The apparatus as claimed in claim 1, wherein a volume fill factor of the porous connecting body is in a range between 15% and 70%.

6. The apparatus as claimed in claim 1, wherein a degree of filling of the filling material in the pores of the porous connecting body is between 25% and 80%.

7. The apparatus as claimed in claim 1, wherein the filling material comprises a liquid metal.

8. The apparatus as claimed in claim 1, wherein the filling material has a thermal conductivity of at least 10 W/m·K.

9. The apparatus as claimed in claim 1, wherein the filling material has a melting point between 200° C. and 300° C.

10. The apparatus as claimed in claim 1, wherein the filling material has a melting point between 100° C. and 200° C.

11. The apparatus as claimed in claim 1, wherein the filling material has a melting point below 100° C.

12. The apparatus as claimed in claim 1, further comprising a compensating facility to compensate for a change in volume of a filling material that is contained in the connecting body and that is liquid during operation of the apparatus.

13. A method for producing an apparatus, the method comprising:
a) coupling a porous connecting body to the component;
b) filling the porous connecting body with a filling material; and
c) coupling a cooling element to the connecting body.

14. The method as claimed in claim 13, wherein coupling the porous connecting body to the component includes additive manufacturing.

15. The method as claimed in claim 14, further comprising producing a gradient a geometric property of the connecting body.
